(19) United States
(12) Patent Application Publication
(10) Pub. No.: US 2026/0123373 A1
(43) Pub. Date: Apr. 30, 2026

(54) METHOD FOR MANUFACTURING SEMICONDUCTOR STRUCTURE

(71) Applicant: SwaySure Technology Co., Ltd., Shenzhen (CN)

(72) Inventors: Qiang Zhang, Shenzhen (CN); Peng Li, Shenzhen (CN)

(73) Assignee: SwaySure Technology Co., Ltd., Shenzhen (CN)

(21) Appl. No.: 19/325,380

(22) Filed: Sep. 10, 2025

(30) Foreign Application Priority Data
Oct. 25, 2024 (CN) 202411509258.4

(51) Int. Cl. H01L 21/768; H01L 21/02; H01L 21/311; H01L 21/3213

(52) U.S. Cl. CPC H10W 20/076; H10P 14/6339; H10P 50/283; H10P 50/667; H10W 20/075; H10W 20/094; H10W 20/097

(57) ABSTRACT

A method is provided for manufacturing a semiconductor structure. The method includes providing a through hole penetrating a stacked layer and exposing a surface of an interconnecting conductive layer; forming a side wall material layer covering at least a side wall and a bottom of the through hole; forming a protective material layer covering the side wall material layer; performing thermal processing on the protective material layer, to cause the protective material layer to implement a material phase change process; etching and removing materials located at the bottom of the through hole to expose the surface of the interconnecting conductive layer, covering the side wall of the through hole, of the side wall material layer as a side wall layer, and taking a remaining protective material layer covering the side wall layer as a protective layer. Working performance of the semiconductor structure is improved.

### CROSS-REFERENCE TO RELATED APPLICATIONS

This application claims priority to Chinese Patent Application No. 202411509258.4, filed Oct. 25, 2024, the entire disclosure of which is hereby incorporated herein by reference.

### TECHNICAL FIELD

Embodiments of the present disclosure relate to the field of semiconductor manufacturing, and in particular, to a method for manufacturing a semiconductor structure.

### BACKGROUND

A pillar electrical connection structure plays an important role in electronic device, especially in an occasion requiring a high-density, high-reliability, and stable electrical connection. With wide application to integrated circuits, semiconductor devices, encapsulation, etc., the pillar electrical connection structure has provided strong support for improving performance and ensuring reliability of an electronic product.

With rapid development of electronic technologies, the pillar electrical connection structure is also technically innovated and optimized continuously. From an initial simple pillar structure to a current complex three-dimensional structure, the performance and reliability have been significantly improved. Moreover, with ongoing advance of the material science, nanotechnology, and precise manufacturing, the pillar electrical connection structure is also more delicate and efficient in designing and manufacturing.

### SUMMARY

A method for manufacturing a semiconductor structure is provided in embodiments of the present disclosure. In the method, a substrate having an embedded interconnecting conductive layer is provided, wherein the substrate exposes a surface of the interconnecting conductive layer, and a stacked layer is formed over the substrate, and a through hole penetrating the stacked layer is formed to expose the surface of the interconnecting conductive layer. The method further includes forming a sidewall material layer that covers at least a sidewall and a bottom of the through hole, wherein a material of the side wall material layer is silicon oxide, and forming a protective material layer that covers the sidewall material layer, wherein a material of the protective material layer is amorphous silicon. A thermal treatment is performed on the protective material layer to induce a material phase transformation, and an etching process is performed to remove materials located at the bottom of the through hole and above the interconnecting conductive layer so as to expose the surface of the interconnecting conductive layer, wherein a portion of the sidewall material layer covering the sidewall of the through hole serves as a sidewall layer, and the remaining protective material layer covering the sidewall layer serves as a protective layer. Then, the protective layer is removed.

### BRIEF DESCRIPTION OF THE DRAWINGS

FIGS. 1-5 are schematic structural diagrams corresponding to all steps in a method for manufacturing a semiconductor structure in the prior art;

FIGS. 6-12 are schematic structural diagrams corresponding to all steps in one embodiment of a method for manufacturing a semiconductor structure according to the present disclosure;

FIGS. 13-15 are schematic structural diagrams corresponding to all steps in another embodiment of the method for manufacturing a semiconductor structure according to the present disclosure; and

FIG. 16 is a schematic structural diagram corresponding to all steps in yet another embodiment of the method for manufacturing a semiconductor structure according to the present disclosure.

### DETAILED DESCRIPTION

It can be known from the background of the disclosure that it is difficult to improve working performance of a semiconductor structure at present. The reason why the working performance of the semiconductor structure remains to be improved is analyzed now with reference to a method for manufacturing a semiconductor structure.

FIG. 1 to FIG. 5 are schematic structural diagrams corresponding to all steps in a method for manufacturing a semiconductor structure respectively.

With reference to FIG. 1, a substrate 10 is provided, where an interconnecting conductive layer 11 is embedded in the substrate 10, the substrate 10 exposes a surface of the interconnecting conductive layer 11, a stacked layer 20 covering the substrate 10 is formed on the substrate 10, and a through hole 21 penetrating the stacked layer 20 and exposing the surface of the interconnecting conductive layer 11 is formed in the stacked layer 20.

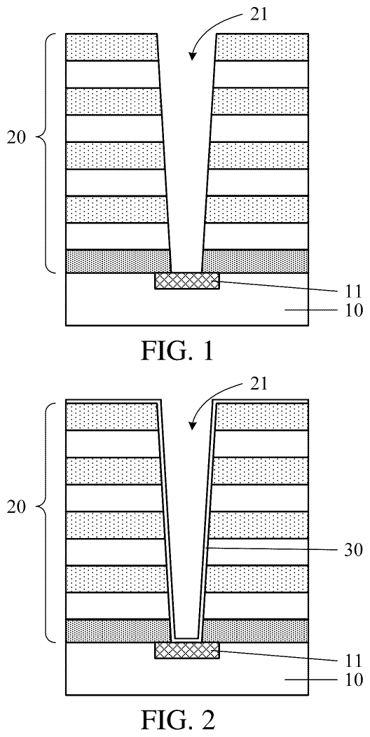

With reference to FIG. 2, a side wall material layer 30 covering at least a side wall and a bottom of the through hole 21 is formed. A material of the side wall material layer 30 is silicon oxide.

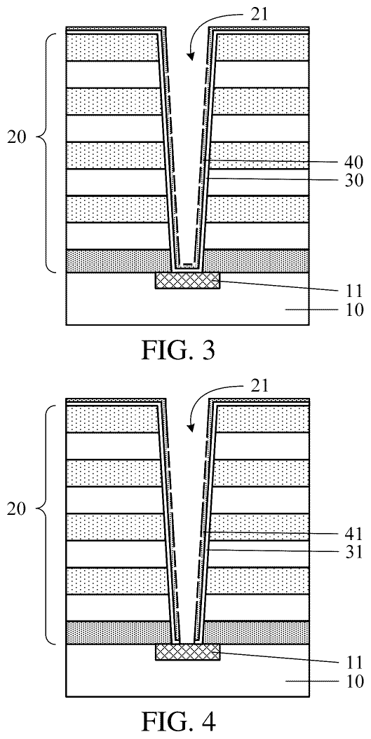

With reference to FIG. 3, a protective material layer 40 covering the side wall material layer 30 is formed. A material of the protective material layer 40 is amorphous silicon.

With reference to FIG. 4, materials located at the bottom of the through hole 21 and above the interconnecting conductive layer 11 are etched and removed, to expose the surface of the interconnecting conductive layer 11. Moreover, a portion, covering the side wall of the through hole 21, of the side wall material layer 30 is taken as a side wall layer 31, and a portion, covering the side wall layer 31, of the protective material layer 40 is taken as a protective layer 41.

The material of the protective material layer 40 is the amorphous silicon, the through hole 21 has a great depth-to-width ratio and a small critical dimension (CD), and the amorphous silicon protective material layer 40 generally has a small thickness. Thus, film discontinuity is caused. To be specific, a film layer has pinhole defects. In a process of removing the materials located at the bottom of the through hole 21 and above the interconnecting conductive layer 11 through dry etching, in the presence of pinholes, a protection effect of the protective material layer 40 on the side wall material layer 30 is weak, and dry-etching damage to the side wall material layer 30 may be caused through the pinholes.

Moreover, the materials located at the bottom of the through hole 21 and above the interconnecting conductive layer 11 need to be removed through dry etching. Thus, an etching residual caused by dry etching is likely to remain at the bottom of the through hole 21, and cleaning processing is also required before the protective layer 41 is removed subsequently. The film layer of the protective layer 41 has the pinhole defect. In consequence, during the cleaning processing, a cleaning liquid is likely to penetrate the protective layer 41, thereby damaging the side wall layer 31. Moreover, an etching liquid is also likely to penetrate the protective layer 41, thereby damaging the side wall layer 31 when the protective layer 41 is removed subsequently through wet etching. In addition, the materials located at the bottom of the through hole 21 and above the interconnecting conductive layer 11 are removed through dry etching. The critical dimension for opening the bottom of the through hole 21 and exposing the interconnecting conductive layer 11 varies obviously in different areas. In consequence, technological critical dimension precision of portions, except for the materials located at the bottom of the through hole 21 and above the interconnecting conductive layer 11 is affected. Thus, critical dimension uniformity of the interconnecting conductive layers 11 exposed from the bottoms of the through holes 21 in different areas is poor. Contact resistance consistency generated when the interconnecting conductive layer 11 is electrically connected through the bottom of the through hole 21 subsequently is undesirable, and the working performance of the semiconductor structure is affected.

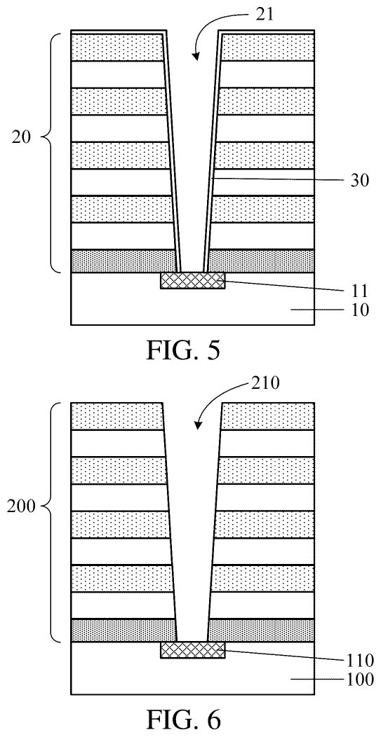

With reference to FIG. 5, the protective layer 41 is removed.

After the protective layer 41 is removed, the interconnecting conductive layer 11 is electrically connected through the bottom of the through hole 21. Owing to the damage to the side wall layer 31, the protection action generated when the interconnecting conductive layer 11 is electrically connected through the bottom of the through hole 21 is likely to be poor, and thus the working performance of the semiconductor structure is affected.

To solve the technical problem, a method for manufacturing a semiconductor structure is provided in the embodiments of the present disclosure. The method includes: a substrate is provided, where an interconnecting conductive layer is embedded in the substrate, the substrate exposes a surface of the interconnecting conductive layer, a stacked layer covering the substrate is formed on the substrate, and a through hole penetrating the stacked layer and exposing the surface of the interconnecting conductive layer is formed in the stacked layer; a side wall material layer covering at least a side wall and a bottom of the through hole is formed, where a material of the side wall material layer is silicon oxide; a protective material layer covering the side wall material layer is formed, where a material of the protective material layer is amorphous silicon; thermal processing is performed on the protective material layer, to cause the protective material layer to implement a material phase change process; materials located at the bottom of the through hole and above the interconnecting conductive layer are etched and removed, to expose the surface of the interconnecting conductive layer, a portion, covering the side wall of the through hole, of the side wall material layer is taken as a side wall layer, and a remaining protective material layer covering the side wall layer is taken as a protective layer; and the protective layer is removed.

In the embodiments of the present disclosure, before the materials located at the bottom of the through hole and above the interconnecting conductive layer are etched and removed, the thermal processing is performed on the protective material layer, to cause the protective material layer to implement the material phase change process. Thus, pinhole defects in the protective material layer are eliminated through lattice reorganization in a conversion process from the amorphous silicon to polycrystalline silicon, and a film forming effect of the protective material layer is improved. In the step that materials located at the bottom of the through hole and above the interconnecting conductive layer are etched and removed, to expose the surface of the interconnecting conductive layer, the protection action of the portion, on the side wall of the through hole, of the protective material layer on the side wall material layer is improved. Moreover, damage to portions, on two sides of the bottom of the through hole, of the side wall material layer due to the pinhole defects when the portions, at the bottom of the through hole, of the protective material layer and the side wall material layer are removed is avoided or alleviated. Thus, a film layer quality of the side wall layer is improved, the protection action of the side wall layer generated when the interconnecting conductive layer is electrically connected through the bottom of the through hole is improved, the electrical leakage is reduced or avoided, and the working performance of the semiconductor structure is improved.

To make the objectives, features, and advantages of the present disclosure more obvious and understandable, specific embodiments of the present disclosure are described in detail below with reference to the accompanying drawings.

FIG. 6 to FIG. 12 are schematic structural diagrams corresponding to all steps in one embodiment of a method for manufacturing a semiconductor structure according to the present disclosure respectively.

With reference to FIG. 6, a substrate 100 is provided, where an interconnecting conductive layer 110 is embedded in the substrate 100, the substrate 100 exposes a surface of the interconnecting conductive layer 110, a stacked layer 200 covering the substrate 100 is formed on the substrate 100, and a through hole 210 penetrating the stacked layer 200 and exposing the surface of the interconnecting conductive layer 110 is formed in the stacked layer 200.

The substrate 100 is used for providing a technological operation basis for a technology for manufacturing a semiconductor structure.

In the embodiment, the interconnecting conductive layer 110 is embedded in the substrate 100, and the substrate 100 exposes the surface of the interconnecting conductive layer 110.

The interconnecting conductive layer 110 is used for an external electrical connection, to implement a basic circuit. The substrate 100 exposes the surface of the interconnecting conductive layer 110, so that the interconnecting conductive layer 110 is electrically connected to the outside through the surface exposed from the substrate 100.

In the embodiment, a material of the interconnecting conductive layer 110 is a metal.

As an example, in the embodiment, the interconnecting conductive layer 110 is a bottom metal.

The stacked layer 200 is used for providing a technological operation basis for forming the through hole 210.

Specifically, in the embodiment, the stacked layer 200 includes an etching stop layer (not shown) located at a bottommost portion.

The etching stop layer is used as an etching stop position generated when the through hole 210 is formed. Thus, the through hole 210 is formed more simply, conveniently, and precisely, and height consistency of the through holes 210 in different areas is improved.

The through hole 210 is used for providing a spatial position for subsequently forming the side wall layer and an interconnecting structure that implements an electrical connection between the interconnecting conductive layer 110 and the outside.

In the embodiment, the through hole 210 penetrates the stacked layer 200 and exposes the surface of the interconnecting conductive layer 110. Thus, the interconnecting structure subsequently formed in the through hole 210 and the interconnecting conductive layer 110 are in contact with each other, to be electrically connected to each other.

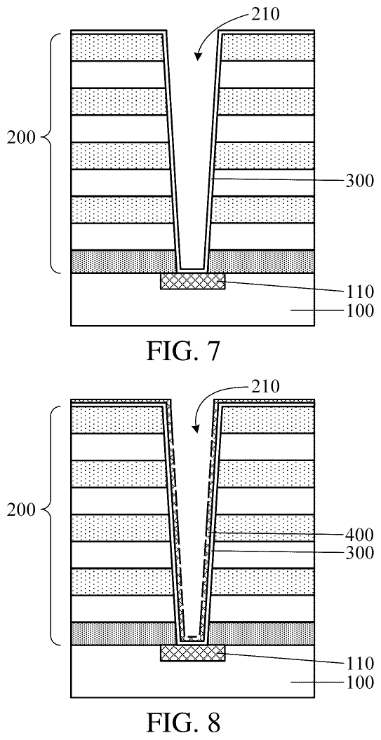

With reference to FIG. 7, a side wall material layer 300 covering at least a side wall and a bottom of the through hole 210 is formed. A material of the side wall material layer 300 is silicon oxide.

The side wall material layer 300 is used for subsequently forming the side wall layer.

In the embodiment, the material of the side wall material layer 300 is the silicon oxide, so that isolation performance and a protection capability of the side wall layer subsequently formed are desirable. Moreover, a sacrificed layer covering the side wall material layer 300 is further formed subsequently. If a material of the sacrificed layer is silicon oxide, according to the material silicon oxide of the sacrificed layer, a portion, at the bottom of the through hole 210, of the side wall material layer 300 and the sacrificed layer are connected into an integrated structure. Thus, the sacrificed layer and the portion, at the bottom of the through hole 210, of the side wall material layer 300 are likely to be removed in the same procedure.

Specifically, in the embodiment, in the step that a side wall material layer 300 covering at least a side wall and a bottom of the through hole 210 is formed, the side wall material layer 300 further covers a top of the stacked layer 20.

In the embodiment, the side wall material layer 300 covering at least the side wall and the bottom of the through hole 210 is formed through an atomic layer deposition (ALD) technology.

The side wall material layer 300 formed through the atomic layer deposition technology has good thickness uniformity and a desirable step coverage capability. Thus, the side wall material layer 300 can well conformally cover the bottom and the side wall of the through hole 210 and the top of the stacked layer 200. Moreover, the side wall layer subsequently formed has desirable thickness uniformity.

With reference to FIG. 8, a protective material layer 400 covering the side wall material layer 300 is formed. A material of the protective material layer 400 is amorphous silicon.

The protective material layer 400 is used for protecting the side wall material layer 300 in subsequent procedures.

In the embodiment, the material of the protective material layer 400 is the amorphous silicon (A-Si), which is conducive to formation of the protective material layer 400 having desirable continuity and uniformity. Moreover, the material amorphous silicon may be converted into polycrystalline silicon subsequently through lattice reorganization based on the thermal processing, so that pinhole defects are eliminated as much as possible.

Specifically, in the embodiment, in the step that a protective material layer 400 covering the side wall material layer 300 is formed, the protective material layer 400 covers portions, located on the side wall and the bottom of the through hole 210, of the side wall material layer 300, and a portion, located at the top of the stacked layer 200, of the side wall material layer 300.

In the embodiment, the protective material layer 400 covering the side wall material layer 300 is formed through a chemical vapor deposition (CVD) technology.

The chemical vapor deposition technology has a high deposition rate and a desirable deposition effect. Thus, the protective material layer 400 with desirable film layer continuity is formed efficiently.

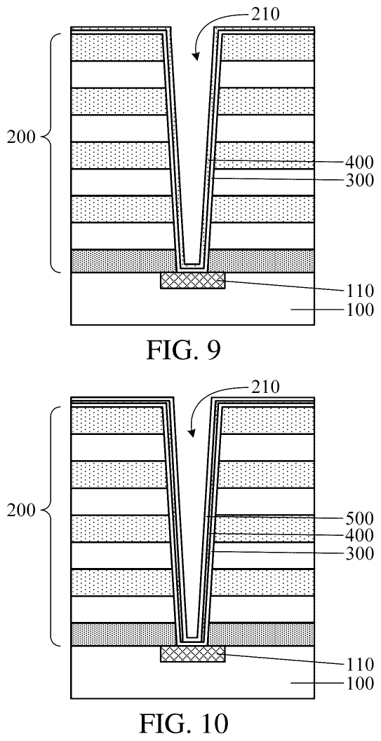

With reference to FIG. 9, the thermal processing is performed on the protective material layer 400, to cause the protective material layer 400 to implement the material phase change process.

The thermal processing is performed on the protective material layer 400, to cause the protective material layer 400 to implement the material phase change process. To be specific, the amorphous silicon is converted into the polycrystalline silicon through the lattice reorganization. Thus, the pinhole defects in the protective material layer 400 are eliminated as much as possible, and the protection action of the protective material layer 400 on the side wall material layer 300 is improved.

In the embodiment, in the step that thermal processing is performed on the protective material layer 400, the material of the protective material layer 400 is converted from the amorphous silicon to the polycrystalline silicon.

Specifically, through the thermal processing, the amorphous silicon undergoes the lattice reorganization, to be converted into the polycrystalline silicon. The polycrystalline silicon formed has fewer pinhole defects.

In the embodiment, in the step that thermal processing is performed on the protective material layer 400, the thermal processing includes rapid thermal processing (RTP).

The rapid thermal processing features high efficiency, flexibility, low pollution, low energy consumption, etc., and thus can perform efficient and rapid thermal processing on the protective material layer 400.

With reference to FIG. 10, after the thermal processing is performed on the protective material layer 400, and before the materials located at the bottom of the through hole 210 and above the interconnecting conductive layer 110 are etched and removed, the manufacturing method further includes: oxidation processing is performed on the protective material layer 400, to completely oxidize a portion, at the bottom of the through hole 210, of the protective material layer 400 and partially oxidize a portion, on the side wall of the through hole 210, of the protective material layer 400; and a sacrificed layer 500 is formed, where the sacrificed layer 500 covers at least a remaining protective material layer 400 on the side wall of the through hole 210.

The oxidation processing is performed on the protective material layer 400, to completely oxidize the portion, at the bottom of the through hole 210, of the protective material layer 400 and partially oxidize the portion, on the side wall of the through hole 210, of the protective material layer 400; and the sacrificed layer 500 is formed. Thus, the sacrificed layer 500 may be removed subsequently through a wet etching technology. When to be removed, the sacrificed layer 500 may have a great etching selection ratio with the remaining protective material layer 400, so that the sacrificed layer 500 is likely to be removed, and the remaining protective material layer 400 is retained. Moreover, the portion, at the bottom of the through hole 210, of the protective material layer 400 is completely oxidized, and the portion, on the side wall of the through hole 210, of the protective material layer 400 is partially oxidized. When the sacrificed layer 500 is removed subsequently, the portion, at the bottom of the through hole 210, of the protective material layer 400 may be completely removed to expose the portion, at the bottom of the through hole 210, of the side wall material layer 300. Then, the portion, at the bottom of the through hole 210, of the side wall material layer 300, and the portion, on the side wall of the through hole 210 and having a particular thickness, of the protective material layer 400 may be further removed. The remaining protective material layer 400 is retained to protect the portion, on the side wall of the through hole 210, of the side wall material layer 300, and thus the portion, on the side wall of the through hole 210, of the side wall material layer 300 can be protected in an etching process.

Specifically, in the embodiment, the sacrificed layer 500 further covers a remaining protective material layer 400 at the top of the stacked layer 200.

It should be noted that in the embodiment, in the step that a protective material layer 400 covering the side wall material layer 300 is formed, based on a limitation of silicon deposition step coverage, a portion, at another position, of the side wall material layer 300 has a greater thickness than the portion, at a bottom position, of the side wall material layer 300. The greater the depth-to-width ratio of the through hole 210 is, the more obvious the thickness difference is. Thus, in the step that oxidation processing is performed on the protective material layer 400, the portion, on the side wall of the through hole 210, of the protective material layer 400 may partially oxidized while the portion, at the bottom of the through hole 210, of the protective material layer 400 may be completely oxidized.

Moreover, in the step that a protective material layer 400 covering the side wall material layer 300 is formed, a thickness of the portion, at the bottom of the through hole 210, of the protective material layer 400 is obtained. Then, a thickness of a portion, at the bottom of the through hole 210, of the silicon oxide sacrificed layer 500 obtained after oxidation is calculated according to a formula for calculating the polycrystalline silicon consumed by oxidizing the polycrystalline silicon to form the silicon oxide. Finally, a technological parameter for performing the oxidation processing on the protective material layer 400 is selected according to the calculated thickness of the portion, at the bottom of the through hole 210, of the silicon oxide sacrificed layer 500. Thus, an oxidation thickness is precisely controlled, so that the portion, at the bottom of the through hole 210, of the protective material layer 400 is completely oxidized, and the portion, on the side wall of the through hole 210, of the protective material layer 400 is partially oxidized.

In the embodiment, in the steps that oxidation processing is performed on the protective material layer 400, to completely oxidize a portion, at the bottom of the through hole 210, of the protective material layer 400 and partially oxidize a portion, on the side wall of the through hole 210, of the protective material layer 400; and a sacrificed layer 500 is formed, a material of the sacrificed layer 500 is silicon oxide.

Correspondingly, in the embodiment, in the step that oxidation processing is performed on the protective material layer 400, the material of the sacrificed layer 500 is the same as the material of the side wall material layer 300.

The material of the sacrificed layer 500 is the same as the material of the side wall material layer 300. Thus, the sacrificed layer 500 and the side wall material layer 300 may be connected into an integrated structure at the bottom of the through hole 210, and the portion, at the bottom of the through hole 210, of the side wall material layer 300 may also be removed in the subsequent step that the sacrificed layer 500 is removed.

In the embodiment, the step that oxidation processing is performed on the protective material layer 400 includes: the oxidation processing is performed on the protective material layer 400 through an in situ steam generation (ISSG) technology or a furnace oxidation technology.

According to the in situ steam generation technology, the film is likely to be formed rapidly, the technological flexibility is high, and pollution is low.

The furnace oxidation technology is good in technological stability, easy to operate, and low in cost.

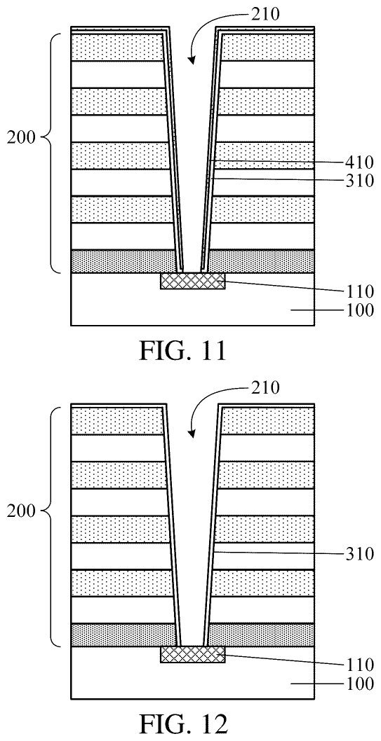

With reference to FIG. 11, materials located at the bottom of the through hole 210 and above the interconnecting conductive layer 110 are etched and removed, to expose the surface of the interconnecting conductive layer 110, a portion, covering the side wall of the through hole 210, of the side wall material layer 300 is taken as a side wall layer 310, and a remaining protective material layer 400 covering the side wall layer 310 is taken as a protective layer 410.

The materials located at the bottom of the through hole 210 and above the interconnecting conductive layer 110 are etched and removed, to expose the surface of the interconnecting conductive layer 110, and thus preparation is made for a subsequent electrical connection between the interconnecting conductive layer 110 and the outside. Moreover, the portion, covering the side wall of the through hole 210, of the side wall material layer 300 is taken as the side wall layer 310 that is used for protecting an interconnecting structure subsequently formed in the through hole 210. The remaining protective material layer 400 covering the side wall layer 310 is taken as the protective layer 410 that is used for protecting the side wall layer 310 in the etching process.

In the embodiment, before the materials located at the bottom of the through hole 210 and above the interconnecting conductive layer 110 are etched and removed, the thermal processing is performed on the protective material layer 400, to cause the protective material layer 400 to implement the material phase change process. Thus, the pinhole defects in the protective material layer 400 are eliminated through the lattice reorganization in the conversion process from the amorphous silicon to the polycrystalline silicon, and a film forming effect of the protective material layer 400 is improved. In the step that materials located at the bottom of the through hole 210 and above the interconnecting conductive layer 110 are etched and removed, to expose the surface of the interconnecting conductive layer 110, the protection action of the portion, on the side wall of the through hole 210, of the protective material layer 400 on the side wall material layer 300 is improved. Moreover, damage to portions, on two sides of the bottom of the through hole 210, of the side wall material layer 300 due to the pinhole defects when the portions, at the bottom of the through hole 210, of the protective material layer 400 and the side wall material layer 300 are removed is avoided or alleviated. Thus, a film layer quality of the side wall layer 310 is improved, and a protection action of the side wall layer 310 generated when the interconnecting conductive layer 110 is electrically connected through the bottom of the through hole 210 is improved. Moreover, the portion, at the bottom of the through hole 210, of the polycrystalline silicon protective material layer is completely oxidized. The material silicon oxide located at the bottom of the through hole 210 and above the interconnecting conductive layer 110 may be removed in one step through wet etching, so that technological critical dimension precision of removing the portions, at the bottom of the through hole 210, of the protective material layer 400 and the side wall material layer 300 is improved. Thus, critical dimension uniformity of the interconnecting conductive layers 110 exposed from the bottoms of the through holes 210 in different areas is improved. Contact resistance consistency generated when the interconnecting conductive layer 110 is electrically connected through the bottom of the through hole 210 is improved, and the working performance of the semiconductor structure is improved.

Correspondingly, in the embodiment, the step that materials located at the bottom of the through hole 210 and above the interconnecting conductive layer 110 are etched and removed includes: the sacrificed layer 500 and the portion, at the bottom of the through hole 210, of the side wall material layer 300 are etched and removed.

The sacrificed layer 500 and the portion, at the bottom of the through hole 210, of the side wall material layer 300 are etched and removed, to expose a top surface of the interconnecting conductive layer 110. The sacrificed layer 500 has the etching selection ratio with the remaining protective material layer 400. The side wall material layer 300 also has an etching selection ratio with the remaining protective material layer 400. Thus, the top surface of the interconnecting conductive layer 110 may be exposed in a process of etching and removing the sacrificed layer 500 and the portion, at the bottom of the through hole 210, of the side wall material layer 300. Moreover, the remaining protective material layer 400 well protects the portion, on the side wall of the through hole 210, of the side wall material layer 300.

In the embodiment, the material of the sacrificed layer 500 is the same as the material of the side wall material layer 500, so that the sacrificed layer 500 and the portion, at the bottom of the through hole 210, of the side wall material layer 300 are etched and removed in the same procedure. Thus, technological efficiency is improved, and a technological cost is saved on.

In the embodiment, the sacrificed layer 500 and the portion, at the bottom of the through hole 210, of the side wall material layer 300 are removed through the wet etching technology.

According to the wet etching technology, a cost is low, operation steps are simple, and a great etching selection ratio is achievable. Thus, damage to the remaining protective material layer 400 in a process of removing the sacrificed layer 500 and the portion, at the bottom of the through hole 210, of the side wall material layer 300 is reduced.

Moreover, the sacrificed layer 500 and the portion, at the bottom of the through hole 210, of the side wall material layer 300 are likely to be removed completely through the wet etching technology, and almost no etching residual remains at the bottom of the through hole 210.

In other embodiments, the sacrificed layer and the portion, at the bottom of the through hole, of the side wall material layer may alternatively be removed through a dry etching technology. After etching, an etching residual is cleaned away. Since the pinhole defects in the protective layer have been basically eliminated in this case, almost no cleaning liquid for cleaning processing damages the side wall layer by penetrating the protective layer, and the film layer quality of the side wall layer is ensured.

It should be noted that in some other embodiments, after the thermal processing is performed on the protective material layer, the step that oxidation processing is performed on the protective material layer may alternatively not performed. The portions, at the bottom of the through hole, of the protective material layer and the side wall material layer are directly etched and removed, and etching is performed through the dry etching technology. After etching, an etching residual is cleaned away. Since the pinhole defects in the protective layer have been basically eliminated in this case, almost no cleaning liquid for cleaning processing damages the side wall layer by penetrating the protective layer, and the film layer quality of the side wall layer is ensured.

With reference to FIG. 12, the protective layer 410 is removed.

The protective layer 410 is removed, so that preparation is made for subsequently forming the interconnecting structure electrically connected to the interconnecting conductive layer 110 in the through hole 210.

In the embodiment, the protective layer 410 is removed through the wet etching technology.

According to the wet etching technology, a cost is low, operation steps are simple, and a great etching selection ratio is achievable. Thus, damage to a remaining side wall layer 310 and the interconnecting conductive layer 110 in a process of removing the protective layer 410 is reduced.

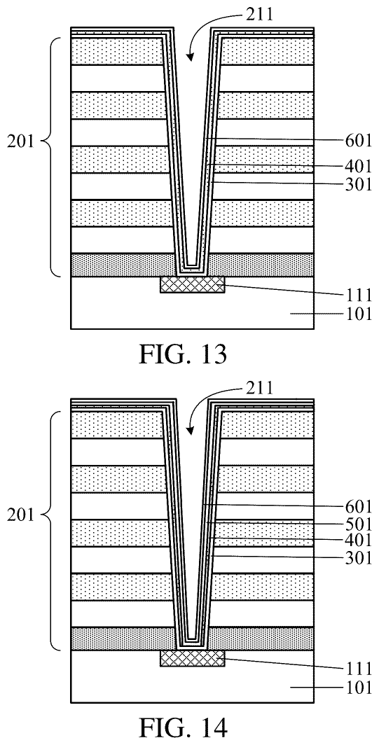

FIG. 13 to FIG. 15 are schematic structural diagrams corresponding to all steps in another embodiment of the method for manufacturing a semiconductor structure according to the present disclosure.

The similarities between the embodiment and the foregoing embodiments will not be repeated herein. A difference between the embodiment and the foregoing embodiments lies in that before the oxidation processing is performed on a protective material layer, a buffer layer covering the protective material layer is further formed.

With reference to FIG. 13, before the oxidation processing is performed on the protective material layer 401, the method further includes: a buffer layer 601 covering the protective material layer 401 is formed.

The buffer layer 601 covering the protective material layer 401 is formed and used for slowing down an oxidation processing rate in a subsequent step that oxidation processing is performed on the protective material layer 401.

Correspondingly, in the embodiment, in the step that a buffer layer 601 covering the protective material layer 401 is formed, the buffer layer 601 covers portions, on a side wall and a bottom of a through hole 211, of the protective material layer 401, and a portion, at a top of a stacked layer 201, of the protective material layer 401.

In the embodiment, in the step that a buffer layer 601 covering the protective material layer 401 is formed, a material of the buffer layer 601 includes any one of silicon oxide, silicon nitride, and silicon oxynitride.

The buffer layer 601 formed by any one of the silicon oxide, the silicon nitride, and the silicon oxynitride can exert a desirable oxidation buffering effect.

In the embodiment, in the step a buffer layer 601 covering the protective material layer 401 is formed, the material of the buffer layer 601 is the same as a material of the sacrificed layer.

The material of the buffer layer 601 is the same as the material of the sacrificed layer subsequently formed. Thus, the buffer layer 601 may also be removed subsequently while the sacrificed layer is removed.

As an example, in the embodiment, in the step that a buffer layer 601 covering the protective material layer 401 is formed, the material of the buffer layer 601 is the silicon oxide. After the oxidation processing is performed on the protective material layer 401 subsequently, the material of the sacrificed layer formed is also the silicon oxide. The buffer layer 601 and the sacrificed layer are made of the same material, and thus may be connected into an integrated structure, and the buffer layer 601 may also be removed subsequently while the sacrificed layer is removed.

In the embodiment, the buffer layer 601 covering the protective material layer 401 is formed through the atomic layer deposition technology.

The buffer layer 601 formed through the atomic layer deposition technology has desirable thickness uniformity and a good step coverage capability. Thus, the buffer layer 601 can well conformally cover the portions, on the side wall and the bottom of the through hole 211, of the protective material layer 401, and the portion, at the top of the stacked layer 201, of the protective material layer 401.

With reference to FIG. 14, after the buffer layer 601 covering the protective material layer 401 is formed, oxidation processing is performed on the protective material layer 401, to completely oxidize the portion, at the bottom of the through hole 211, of the protective material layer 401 and partially oxidize the portion, on the side wall of the through hole 211, of the protective material layer 401; and the sacrificed layer 501 is formed.

In a process of performing the oxidation processing on the protective material layer 401, owing to barrier buffering by the buffer layer 601, an oxidation diffusing rate is slowed down, so that an oxidation technology parameter is more precisely controlled, and an oxidation thickness is more precisely controlled. Thus, the portion, at the bottom of the through hole 211, of the protective material layer 401 is completely oxidized, and the portion, on the side wall of the through hole 211, of the protective material layer 401 is partially oxidized.

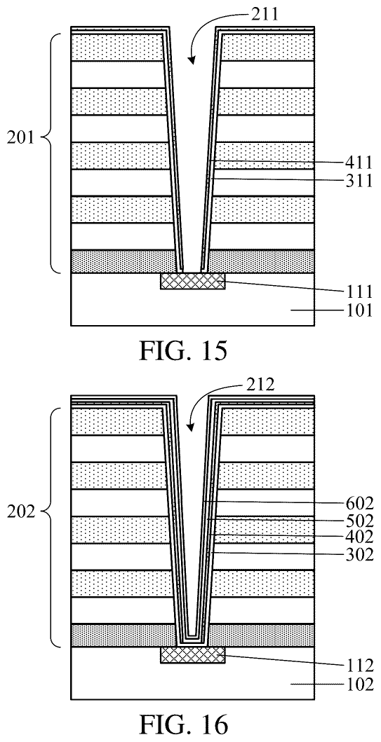

With reference to FIG. 15, in a step that the sacrificed layer 501 and a portion, at the bottom of the through hole 211, of a side wall material layer 311 are etched and removed, the method further includes: the buffer layer 601 is removed.

The buffer layer 601 is removed, to expose a top surface of an interconnecting conductive layer 111 in a substrate 101.

In the embodiment, the material of the buffer layer 601 is the same as the material of the sacrificed layer 501. Correspondingly, the sacrificed layer 501 and the buffer layer 601 are removed in the same procedure, so that technological efficiency is improved, and a technological cost is reduced.

FIG. 16 is a schematic structural diagram corresponding to all steps in yet another embodiment of the method for manufacturing a semiconductor structure according to the present disclosure.

The similarities between the embodiment and the foregoing embodiments will not be repeated herein. A difference between the embodiment and the foregoing embodiment lies in that: a sacrificed layer is formed by forming a buffer layer covering a protective material layer.

With reference to FIG. 16, a step that oxidation processing is performed on the protective material layer 402 includes: the buffer layer 602 covering the protective material layer 402 is formed, where a material of the buffer layer 602 is oxide; oxidation is diffused from the buffer layer 602 into the protective material layer 402 while the buffer layer 602 is formed, to completely oxidize a portion, at a bottom of a through hole 212, of the protective material layer 402 and partially oxidize a portion, on a side wall of the through hole 212, of the protective material layer 402; and the sacrificed layer 502 is formed.

The material of the buffer layer 602 is the oxide. Thus, in a process of forming the buffer layer 602 covering the protective material layer 402, an amount of oxygen introduced is appropriately increased. The oxidation may be diffused into the protective material layer 402 while the buffer layer 602 is formed. The portion, at the bottom of the through hole 212, of the protective material layer 402 is completely oxidized, and the portion, on the side wall of the through hole 212, of the protective material layer 402 is partially oxidized, to form the sacrificed layer 502.

In the embodiment, the sacrificed layer 502 is formed while the buffer layer 602 covering the protective material layer 402 is formed. Thus, a technological flow is simplified, technological efficiency is improved, and a technological cost is saved on.

As an example, in the embodiment, the buffer layer 602 covering the protective material layer 402 is formed. The material of the buffer layer 602 is silicon oxide.

It should be noted that in the embodiment, after the buffer layer 602 covering the protective material layer 402 is formed, the step that oxidation processing is performed on the protective material layer 402 through the in situ steam generation technology or the furnace oxidation technology may alternatively be performed or not.

The present disclosure is described above, but which is not intended to limit the present disclosure. Any person skilled in the art can make various alterations and modifications without departing from the spirit and scope of the present disclosure. Thus, the scope of protection of the present disclosure should be subject to the scope defined by the claims.

What is claimed is:

1. A method for manufacturing a semiconductor structure, comprising:
providing a substrate, wherein an interconnecting conductive layer is embedded in the substrate, the substrate exposes a surface of the interconnecting conductive layer, a stacked layer covering the substrate is formed on the substrate, and a through hole penetrating the stacked layer and exposing the surface of the interconnecting conductive layer is formed in the stacked layer;
forming a side wall material layer covering at least a side wall and a bottom of the through hole, wherein a material of the side wall material layer is silicon oxide;
forming a protective material layer covering the side wall material layer, wherein a material of the protective material layer is amorphous silicon;
performing thermal processing on the protective material layer, to cause the protective material layer to implement a material phase change process;
etching and removing materials located at the bottom of the through hole and above the interconnecting conductive layer, to expose the surface of the interconnecting conductive layer, taking a portion, covering the side wall of the through hole, of the side wall material layer as a side wall layer, and taking a remaining protective material layer covering the side wall layer as a protective layer; and
removing the protective layer.

2. The method for manufacturing a semiconductor structure according to claim 1, wherein in the performing thermal processing on the protective material layer, the material of the protective material layer is converted from the amorphous silicon into polycrystalline silicon.

3. The method for manufacturing a semiconductor structure according to claim 1, wherein in the performing thermal processing on the protective material layer, the thermal processing comprises rapid thermal processing.

4. The method for manufacturing a semiconductor structure according to claim 1, wherein after the thermal processing is performed on the protective material layer, and before the materials located at the bottom of the through hole and above the interconnecting conductive layer are etched and removed, the method further comprises: performing oxidation processing on the protective material layer, to completely oxidize a portion, at the bottom of the through hole, of the protective material layer and partially oxidize a portion, on the side wall of the through hole, of the protective material layer; and forming a sacrificed layer, wherein the sacrificed layer covers at least the remaining protective material layer on the side wall of the through hole.

5. The method for manufacturing a semiconductor structure according to claim 4, wherein the etching and removing materials located at the bottom of the through hole and above the interconnecting conductive layer comprise: etching and removing the sacrificed layer and a portion, at the bottom of the through hole, of the side wall material layer.

6. The method for manufacturing a semiconductor structure according to claim 5, wherein in the performing oxidation processing on the protective material layer, a material of the sacrificed layer is the same as the material of the side wall material layer; and
the sacrificed layer and the portion, at the bottom of the through hole, of the side wall material layer are etched and removed in the same procedure.

7. The method for manufacturing a semiconductor structure according to claim 4, wherein the performing oxidation processing on the protective material layer comprises: performing the oxidation processing on the protective material layer through an in situ steam generation technology or a furnace oxidation technology.

8. The method for manufacturing a semiconductor structure according to claim 5, wherein the sacrificed layer and the portion, at the bottom of the through hole, of the side wall material layer are removed through a wet etching technology.

9. The method for manufacturing a semiconductor structure according to claim 5, wherein before the oxidation processing is performed on the protective material layer, the method further comprises: forming a buffer layer covering the protective material layer; and
the etching and removing the sacrificed layer and a portion, at the bottom of the through hole, of the side wall material layer further comprise: removing the buffer layer.

10. The method for manufacturing a semiconductor structure according to claim 9, wherein in the forming a buffer layer covering the protective material layer, a material of the buffer layer comprises any one of silicon oxide, silicon nitride, and silicon oxynitride.

11. The method for manufacturing a semiconductor structure according to claim 5, wherein the performing oxidation processing on the protective material layer comprises: forming a buffer layer covering the protective material layer, wherein a material of the buffer layer is oxide; diffusing oxidation from the buffer layer into the protective material layer while the buffer layer is formed, to completely oxidize the portion, at the bottom of the through hole, of the protective material layer and partially oxidize the portion, on the side wall of the through hole, of the protective material layer; and forming the sacrificed layer; and
the etching and removing the sacrificed layer and a portion, at the bottom of the through hole, of the side wall material layer further comprise: removing the buffer layer.

12. The method for manufacturing a semiconductor structure according to claim 9, wherein the buffer layer covering the protective material layer is formed through an atomic layer deposition technology.

13. The method for manufacturing a semiconductor structure according to claim 11, wherein the buffer layer covering the protective material layer is formed through an atomic layer deposition technology.

14. The method for manufacturing a semiconductor structure according to claim 9, wherein in the forming a buffer layer covering the protective material layer, the material of the buffer layer is the same as a material of the sacrificed layer; and
the sacrificed layer and the buffer layer are removed in the same procedure.

15. The method for manufacturing a semiconductor structure according to claim 11, wherein in the forming a buffer layer covering the protective material layer, the material of the buffer layer is the same as a material of the sacrificed layer; and
the sacrificed layer and the buffer layer are removed in the same procedure.

16. The method for manufacturing a semiconductor structure according to claim 1, wherein the side wall material layer covering at least the side wall and the bottom of the through hole is formed through an atomic layer deposition technology.

17. The method for manufacturing a semiconductor structure according to claim 1, wherein the protective material layer covering the side wall material layer is formed through a chemical vapor deposition technology.

18. The method for manufacturing a semiconductor structure according to claim 1, wherein the protective layer is removed through a wet etching technology.
